(19) United States
(12) Patent Application Publication
(10) Pub. No.: US 2026/0119760 A1
(43) Pub. Date: Apr. 30, 2026

(54) INSULATING MEDIUM DISCHARGE STREAMER SIMULATION METHOD AND SYSTEM CONSIDERING OFFSET AND BIFURCATION

(71) Applicant: XI'AN JIAOTONG UNIVERSITY, Xi'an (CN)

(72) Inventors: Simeng LI, Xi'an (CN); Zewei BU, Xi'an (CN); Zhihua LIU, Xi'an (CN); Yongliang DANG, Xi'an (CN); Shengchang JI, Xi'an (CN)

(21) Appl. No.: 19/432,528

(22) Filed: Dec. 24, 2025

Related U.S. Application Data
(63) Continuation-in-part of application No. 17/885,261, filed on Aug. 10, 2022.

(30) Foreign Application Priority Data
Jan. 30, 2022 (CN) 2022101138155

(51) Int. Cl. G06F 30/28

(52) U.S. Cl. CPC G06F 30/28

(57) ABSTRACT

Disclosed is a discharge streamer simulation method and system considering offset and bifurcation. The system includes a test platform, a high-voltage excitation unit, an optical imaging unit, and a data processing & simulation unit. The data processing & simulation unit comprises a computer system. The computer system's processor is configured to: receive discharge images from the camera; measure, from the images, ranges for bifurcation points and effective electron avalanches; construct and execute a simulation model based on specified physical models. The system integrates physical testing with simulation to accurately describe stochastic streamer behavior, and is applicable to guide the development of insulating medium materials and the design of insulation systems.

### CROSS-REFERENCE TO RELATED APPLICATIONS

This application is a continuation-in-part of U.S. application Ser. No. 17/885,261. This application claims priorities from U.S. application Ser. No. 17/885,261, filed Aug. 10, 2022, and from the Chinese patent application 2022101138155 filed Jan. 30, 2022, the content of which are incorporated herein in the entirety by reference.

### TECHNICAL FIELD

The present disclosure belongs to the technical field of insulating medium streamer discharge, and in particular, to an insulating medium discharge streamer simulation method and system considering offset and bifurcation.

### BACKGROUND

Oil-paper insulation is one of the most common forms of solid-liquid insulation in an electric power system. The discharge characteristics and mechanism of the oil-paper insulation have attracted much attention. In particular, the mathematical description and the simulation method of the discharge phenomenon in the oil-paper insulation have become a research hotspot. Simulation calculation not only becomes an effective supplement to experimental means, but also is the only way to explore the discharge characteristics and mechanism without the experimental conditions. However, the existing simulation model has difficulty in reflecting the randomness and dispersibility, resulting in that it is still difficult to simulate the offset and bifurcation of the discharge streamer.

In the prior art, random disturbance points (position, number and size are all random) are arranged in oil, so that bifurcation and offset phenomena are generated after the streamer arrives at the disturbance points. However, on one hand, the introduction of the random disturbance points will greatly increase the mesh generation number, increase the calculation amount and occupy the calculation resource; and on the other hand, the random disturbance points reflect the macroscopic random characteristic, for example, bubbles and impurities in the oil, oil flow disturbance and uneven local distribution, and the streamer bifurcation and offset phenomena will also occur in the pure isotropous oil. In addition, the size range and the density range of the random disturbance points are not supported by a mature theory. Therefore, it is necessary to study a method for describing streamer bifurcation and offset under the driving of microscopic mechanism based on the generation and development probability of microscopic electron avalanches.

The above information disclosed in the Background section is merely used to enhance the understanding of the background of the present disclosure; therefore, information which does not constitute the prior art known to those of ordinary skill in the art may be included.

### SUMMARY

Existing streamer simulation cannot effectively and rapidly describe the streamer offset and bifurcation phenomena. An objective of the present disclosure is to provide an insulating medium streamer discharge simulation method, so as to effectively and rapidly describe streamer bifurcation and offset based on the electron avalanche development probability theory. In order to achieve the above objective, the present disclosure provides the following technical solution.

An insulating medium discharge streamer simulation method considering offset and bifurcation provided by the present disclosure includes:

First step: arranging an insulating medium in an electric field environment, measuring the number range [Nₚₛ, N_{pb}] of discharge streamer bifurcation points in the insulating medium and the number range of [N_{bs}, N_{bb}] of effective electron avalanches generated by each bifurcation, randomly drawing N_{bpoint}∈[Nₚₛ,N_{pb}] bifurcation points from all simulation calculation time nodes and marking corresponding moments as bifurcation moments, wherein Nₚₛ and N_{pb} the minimum value and the maximum value of the number of the discharge streamer bifurcation points respectively, N_{bs} and N_{bb} are the minimum value and the maximum value of the effective electron avalanches respectively, and N_{bpoint} is the number of the randomly drawn bifurcation points;

Second step: constructing a simulation model for discharge streamer in the insulating medium based on a hydrodynamic drift diffusion model and a bipolar charge carrier migration model, wherein the initial value a₀ of the average distance between molecules in the hydrodynamic drift diffusion model is set as a real constant greater than 0; performing calculation according to a specified simulation step length from the zero moment, if the calculation reaches the bifurcation moment, entering the third step and then continuing to perform calculation after the value of the average distance between molecules is updated, otherwise, continuing to perform calculation with the values of the original parameters, and ending after simulation calculation is performed for a specified simulation duration;

Third step: calculating the probability of bifurcation occurring at each streamer head at a certain bifurcation moment:

$${P}_{s - i} = \{ \begin{matrix}\frac{{\vert {E}_{smax - i} \vert}^{η}}{{\sum }_{i = 1}^{{n}_{s}} {\vert {E}_{smax - i} \vert}^{η}} & \vert {E}_{smax - i} \vert > {E}_{c} \\ 0 & \vert {E}_{smax - i} \vert \leq {E}_{c}\end{matrix} i = 1 , 2 , … , {n}_{s} ,$$

wherein i is a serial number parameter, nₛ is the total number of all streamer branches at the current moment, Pₛ₋ᵢ is the probability of bifurcation occurring at the i^{th} streamer head, Eₛₘₐₓ₋ᵢ is the maximum electric field intensity of the i^{th} streamer head, E_{c} is the threshold of the electric field for sustainable development of the streamer, the streamer with Eₛₘₐₓ₋ᵢ>E_{c} is a developable streamer, and η is the streamer development probability index

Fourth step: drawing a streamer bifurcation position according to the Pₛ₋ᵢ, wherein only one bifurcation position is drawn at each bifurcation moment, the drawn streamer is referred to as a to-be-bifurcated streamer, the bifurcation position at the position of the maximum field intensity of the head is denoted as (x₀,y₀,z₀), x₀ is the X-axis coordinates of the bifurcation position, y₀ is the Y-axis coordinates of the bifurcation position, and z₀ is the Z-axis coordinates of the bifurcation position;

Fifth step: making a 180° cambered surface or arc by taking the bifurcation position as a center of a circle and 1-5 times the radius rs of the head of the streamer as a radius, wherein the rₛ is a distance between the position of the maximum net charge density and the position of the maximum electric field intensity; dividing the cambered surface or arc into nᵣ to-be-developed points at equal grids or equal intervals, wherein nᵣ>(5×N_{bb}) is met and nᵣ is the number of the to-be-developed points; and calculating the probability of the effective electron avalanches moving and evolving to each to-be-developed point:

$${P}_{b - j} = \{ \begin{matrix}\frac{{\vert {ϕ}_{smax} - {ϕ}_{j} \vert}^{η}}{{\sum }_{j = 1}^{{n}_{r}} {\vert {ϕ}_{smax} - {ϕ}_{j} \vert}^{η}} & \vert {ϕ}_{smax} - {ϕ}_{j} \vert > {ϕ}_{c} \\ 0 & \vert {ϕ}_{smax} - {ϕ}_{j} \vert \leq {ϕ}_{c}\end{matrix} j = 1 , 2 , … , {n}_{r} ,$$

wherein j is a serial number parameter, P_{b-j} is the probability of the effective avalanches moving to the j^{th} to-be-developed point, φₛₘₐₓ is the electric potential at the bifurcation position, φⱼ is the electric potential at the j^{th} to-be-developed point, η is the streamer development probability index, and φ_{c} is a threshold of the effective electron avalanche development electric potential;

Sixth step: randomly drawing N_{branch}∈[N_{bs}, N_{bb}] effective development points from the nr to-be-developed points according to the P_{b-j}, wherein N_{branch} is the total number of the effective development points, and it is indicated that the streamer only offsets but is not bifurcated when N_{branch}=1; connecting (x₀,y₀,z₀) with the selected to-be-developed point (xₖ,yₖ,zₖ) to form a vector pointing at the to-be-developed point which is regarded as the development direction of the effective electron avalanches, wherein xₖ is the X-axis coordinates of the k^{th} effective development point, yₖ is the Y-axis coordinates of the k^{th} effective development point, zₖ is the Z-axis coordinates of the k^{th} effective development point, and k=1, 2, . . . , N_{branch};

Seventh step: taking a plane of which the normal vector is parallel to the development direction of the to-be-bifurcated streamer and which passes through a point (x₀,y₀,z₀) as a boundary, or taking a straight line which is perpendicular to the development direction of the to-be-developed streamer and passes through a point (x₀,y₀,z₀) as a boundary, and on the to-be-developed side, calculating a distance dₖ(x,y,z) from a certain point (x,y,z) in a solving domain to a ray where the development direction of each branch is located:

$${d}_{k} ( x , y , z ) = \{ \begin{matrix}\begin{matrix}\begin{matrix}\begin{matrix}a distance to a straight line \\ passing through the point\end{matrix} \\ ( {x}_{0} , {y}_{0} , {z}_{0} ) and the point\end{matrix} \\ ( {x}_{k} , {y}_{k} , {z}_{k} )\end{matrix} & \begin{matrix}\begin{matrix}( {x}_{0} - {x}_{k} ) ( {x}_{0} - x ) + \\ ( {y}_{0} - {y}_{k} ) ( {y}_{0} - y ) +\end{matrix} \\ ( {z}_{0} - {z}_{k} ) ( {z}_{0} - z ) \geq 0\end{matrix} \\ \begin{matrix}a distance to the point \\ ( {x}_{0} , {y}_{0} , {z}_{0} )\end{matrix} & \begin{matrix}\begin{matrix}( {x}_{0} - {x}_{k} ) ( {x}_{0} - x ) + \\ ( {y}_{0} - {y}_{k} ) ( {y}_{0} - y ) +\end{matrix} \\ ( {z}_{0} - {z}_{k} ) ( {z}_{0} - z ) < 0\end{matrix}\end{matrix} ,$$

wherein the starting point of the ray is (x0,y0,z0), assuming that the minimum of dk(x,y,z) is dmin(x,y,z), a correction coefficient kcor(x,y,z) is constructed as follows:

$${k}_{cor} ( x , y , z ) = {( \frac{1}{1 + {d}_{min} ( x , y , z )} )}^{γ} ,$$

wherein γ is a gradient parameter for controlling the change rate of the correction coefficient; and

Eighth step: correcting the average distance between molecules in the hydrodynamic drift diffusion model in the solving domain on the to-be-developed side,

$${a}_{cor} ( x , y , z , t ) = ( 1 - m \times {K}_{cor} ( x , y , z ) \times \frac{Δ {T}_{s} - t}{Δ {T}_{s}} ) \times {a}_{0} ,$$

wherein a_{cor} is the corrected average distance between molecules and is a function related to the spatial position and time, m is a correction scaling coefficient and meets 0<m<1, K_{cor} is the normalized result of k_{cor}, a₀ is the initial value of the average distance between molecules in the hydrodynamic drift diffusion model, ΔTₛ is a time interval between the moment of current bifurcation and the moment of next bifurcation and t is the streamer development time calculated from the beginning of current bifurcation; and updating the average distance between molecules of the discharge streamer simulation model in the second step to current corrected value and returning to the second step.

In the insulating medium discharge streamer simulation method considering offset and bifurcation, the positively polar streamer development probability index is 2-3, and the negatively polar streamer development probability index is 1.5-2.

In the insulating medium discharge streamer simulation method considering offset and bifurcation, the gradient parameter γ is greater than 1.

In the insulating medium discharge streamer simulation method considering offset and bifurcation, the electric field threshold E_{c} of the effective electron avalanche development is greater than or equal to 0, and the electric potential difference threshold φ_{c} of the effective electron avalanche development is greater than or equal to 0.

An insulating medium discharge streamer simulation system considering offset and bifurcation, comprising:
a test platform comprising a substantially planar surface for supporting the insulating medium, and a ground electrode electrically connected to said platform;
a high-voltage electrode disposed opposite and spaced apart from said planar surface to form an electric field environment with the ground electrode;
a programmable high-voltage power supply electrically connected to the high-voltage electrode and the ground electrode, configured to apply at least one of AC, DC, composite AC-DC, or pulsed electric stress to the insulating medium;
a high-speed camera positioned to capture real-time discharge images of streamer development within the insulating medium; and
a computer system operatively connected to the high-speed camera, said computer system comprising a processor and a memory storing executable instructions, wherein the processor is configured to:
receive the discharge images from the high-speed camera;
measure, based on analysis of said discharge images, the number range [Nₚₛ, N_{pb}] of discharge streamer bifurcation points in the insulating medium and the number range of [N_{bs}, N_{bb}] of effective electron avalanches generated by each bifurcation, draw N_{bpoint}∈[Nₚₛ,N_{pb}] bifurcation points from all simulation calculation time nodes randomly and mark corresponding moments as bifurcation moments, wherein Nₚₛ and N_{pb} are the minimum value and the maximum value of the number of the discharge streamer bifurcation points respectively, N_{bs} and N_{bb} are the minimum value and the maximum value of the effective electron avalanches respectively, and N_{bpoint} is the number of the randomly drawn bifurcation points;
construct a simulation model for discharge streamer in the insulating medium based on a hydrodynamic drift diffusion model and a bipolar charge carrier migration model, wherein the initial value a₀ of the average distance between molecules in the hydrodynamic drift diffusion model is set as a real constant greater than 0; perform calculation according to a specified simulation step length from the zero moment, wherein if the calculation reaches the bifurcation moment, the processor updates the average distance between molecules and continues calculation, otherwise continues calculation with the values of the original parameters, and end after simulation calculation is performed for a specified simulation duration;
calculate the probability of bifurcation occurring at each streamer head at a certain bifurcation moment:

$${P}_{s - i} = \{ \begin{matrix}\frac{{\vert {E}_{smax - i} \vert}^{η}}{{\sum }_{i = 1}^{{n}_{s}} {\vert {E}_{smax - i} \vert}^{η}} & \vert {E}_{smax - i} \vert > {E}_{c} \\ 0 & \vert {E}_{smax - i} \vert \leq {E}_{c}\end{matrix} i = 1 , 2 , … , {n}_{s} ,$$

wherein i is a serial number parameter, nₛ is the total number of all streamer branches at the current moment, Pₛ₋ᵢ is the probability of bifurcation occurring at the i^{th} streamer head, Eₛₘₐₓ₋ᵢ is the maximum electric field intensity of the i^{th} streamer head, E_{c} is the threshold of the electric field for sustainable development of the streamer, the streamer with Eₛₘₐₓ₋ᵢ>E_{c} is a developable streamer, and η is the streamer development probability index;
draw a streamer bifurcation position according to the Pₛ₋ᵢ, wherein only one bifurcation position is drawn at each bifurcation moment, the drawn streamer is referred to as a to-be-bifurcated streamer, the bifurcation position at the position of the maximum field intensity of the head is denoted as (x0,y0,z0), x₀ is the X-axis coordinates of the bifurcation position, y₀ is the Y-axis coordinates of the bifurcation position, and z₀ is the Z-axis coordinates of the bifurcation position;
make a 180° cambered surface or arc by taking the bifurcation position as a center of a circle and 1-5 times the radius rₛ of the head of the streamer as a radius, wherein the rₛ is a distance between the position of the maximum net charge density and the position of the maximum electric field intensity; divide the cambered surface or arc into nr to-be-developed points at equal grids or equal intervals, wherein nᵣ>(5×N_{bb}) is met and nᵣ is the number of the to-be-developed points; and calculate the probability of the effective electron avalanches moving and evolving to each to-be-developed point:

$${P}_{b - j} = \{ \begin{matrix}\frac{{\vert {ϕ}_{smax} - {ϕ}_{j} \vert}^{η}}{{\sum }_{j = 1}^{{n}_{r}} {\vert {ϕ}_{smax} - {ϕ}_{j} \vert}^{η}} & \vert {ϕ}_{smax} - {ϕ}_{j} \vert > {ϕ}_{c} \\ 0 & \vert {ϕ}_{smax} - {ϕ}_{j} \vert \leq {ϕ}_{c}\end{matrix} j = 1 , 2 , … , {n}_{r} ,$$

wherein j is a serial number parameter, P_{b-j} is the probability of the effective avalanches moving to the j^{th} to-be-developed point, φₛₘₐₓ is the electric potential at the bifurcation position, φⱼ is the electric potential at the j^{th} to-be-developed point, η is the streamer development probability index, and φ_{c} is a threshold of the effective electron avalanche development electric potential;
draw N_{branch}∈[N_{bs}, N_{bb}] effective development points from the nᵣ to-be-developed points randomly according to the P_{b-j}, wherein N_{branch} is the total number of the effective development points, and it is indicated that the streamer only offsets but is not bifurcated when N_{branch}=1; connect (x0,y0,z0) with the selected to-be-developed point (xₖ,yₖ,zₖ) to form a vector pointing at the to-be-developed point which is regarded as the development direction of the effective electron avalanches, wherein xₖ is the X-axis coordinates of the k^{th} effective development point, yₖ is the Y-axis coordinates of the k^{th} effective development point, zₖ is the Z-axis coordinates of the k^{th} effective development point, and k=1, 2, . . . , N_{branch};
take a plane of which the normal vector is parallel to the development direction of the to-be-bifurcated streamer and which passes through a point (x₀,y₀,z₀) as a boundary, or take a straight line which is perpendicular to the development direction of the to-be-developed streamer and passes through a point (x₀,y₀,z₀) as a boundary, and on the to-be-developed side, calculate a distance dₖ(x,y,z) from a certain point (x,y,z) in a solving domain to a ray where the development direction of each branch is located:

$${d}_{k} ( x , y , z ) = \{ \begin{matrix}\begin{matrix}\begin{matrix}\begin{matrix}a distance to a straight line \\ passing through the point\end{matrix} \\ ( {x}_{0} , {y}_{0} , {z}_{0} ) and the point\end{matrix} \\ ( {x}_{k} , {y}_{k} , {z}_{k} )\end{matrix} & \begin{matrix}\begin{matrix}( {x}_{0} - {x}_{k} ) ( {x}_{0} - x ) + \\ ( {y}_{0} - {y}_{k} ) ( {y}_{0} - y ) +\end{matrix} \\ ( {z}_{0} - {z}_{k} ) ( {z}_{0} - z ) \geq 0\end{matrix} \\ \begin{matrix}a distance to the point \\ ( {x}_{0} , {y}_{0} , {z}_{0} )\end{matrix} & \begin{matrix}\begin{matrix}( {x}_{0} - {x}_{k} ) ( {x}_{0} - x ) + \\ ( {y}_{0} - {y}_{k} ) ( {y}_{0} - y ) +\end{matrix} \\ ( {z}_{0} - {z}_{k} ) ( {z}_{0} - z ) < 0\end{matrix}\end{matrix} ,$$

wherein the starting point of the ray is (x₀,y₀,z₀), assuming that the minimum value in dₖ(x,y,z) is dₘᵢₙ(x,y,z), a correction coefficient k_{cor} (x,y,z) is constructed as follows:

$${k}_{cor} ( x , y , z ) = {( \frac{1}{1 + {d}_{min} ( x , y , z )} )}^{γ} ;$$

wherein γ is a gradient parameter for controlling the change rate of the correction coefficient; and
correct the average distance between molecules in the hydrodynamic drift diffusion model in the solving domain on the to-be-developed side,

$${a}_{cor} ( x , y , z , t ) = ( 1 - m \times {K}_{cor} ( x , y , z ) \times \frac{Δ {T}_{s} - t}{Δ {T}_{s}} ) \times {a}_{0} ,$$

wherein a_{cor} is the corrected average distance between molecules and is a function related to the spatial position and time, m is a correction scaling coefficient and meets 0<m<1, K_{cor} is the normalized result of k_{cor}, ΔTₛ is a time interval between the moment of current bifurcation and the moment of next bifurcation and t is the streamer development time calculated from the beginning of current bifurcation; and update the average distance between molecules in the simulation model to current corrected value; and continue the calculation from the point of update, thereby iteratively performing the simulation until the specified simulation duration is reached.

In the insulating medium discharge streamer simulation system considering offset and bifurcation, the system also comprises an output unit coupled to the computer system, configured to display simulation results including space electric field distribution and space charge distribution accompanying the streamer offset and bifurcation.

In the insulating medium discharge streamer simulation system considering offset and bifurcation, wherein the processor is further configured such that when simulating a positively polar streamer, the positively polar streamer development probability index is 2-3, and when simulating a negatively polar streamer, the negatively polar streamer development probability index is 1.5-2.

In the insulating medium discharge streamer simulation system considering offset and bifurcation, wherein the gradient parameter γ is greater than 1.

In the insulating medium discharge streamer simulation system considering offset and bifurcation, wherein the electric field threshold E_{c} of the effective electron avalanche development is greater than or equal to 0, and the electric potential difference threshold de of the effective electron avalanche development is greater than or equal to 0.

In the above technical solution, the insulating medium discharge streamer simulation method considering offset and bifurcation provided by the present disclosure has the following beneficial effects: the simulation description of discharge channel offset and bifurcation is realized based on the electron avalanche development probability; and the method can be used to construct and solve a two-dimensional discharge model or a three-dimensional discharge model. The present disclosure is suitable for all alternating current (power frequency, harmonic wave, square wave and the like), direct current (positive polarity and negative polarity), alternating and direct current composite electric stress and pulse electric stress. The present disclosure not only can be applied to an oil-paper insulating system, but also can be applied to any liquid-solid two-phase insulation system or liquid single-phase insulation system, and it is only necessary to set corresponding parameters according to the dielectric property. The describable discharge phenomenon not only is limited to a space streamer, but also can describe a surface streamer. The correctable parameter of the present disclosure not only is limited to the average distance of molecules, but also may be an ionized molecular density no, an ionized energy coefficient γₑ, a collision ionization coefficient Aₜ and a collision ionization index item coefficient Bₜ, and may be one or several of the above parameters. The correction method is unchanged. If the selected coefficient is positively correlated with a charge generation item, then m∈(−1,0). If the selected coefficient is negatively correlated, m∈(0,1). The radius of the cambered surface (or arc) is 1-5 times rs. This range is only intended to ensure the calculation accuracy. Certainly, this range may be exceeded, as long as it can be ensured that the radius of the cambered surface (or arc) is greater than 0. The solving model in the second step not only is limited to the hydrodynamic drift diffusion model and the bipolar charge carrier model, but also may be other similar streamer solving models.

The insulating medium discharge streamer simulation system considering offset and bifurcation is not merely a mathematical simulation tool but an integrated hardware-software apparatus used in high-voltage insulation laboratories.

It serves to:
Validate and calibrate simulation models against real physical discharge events;
Guide the development of new insulating materials by predicting their discharge behavior under complex electric stresses;
Improve the design of insulation systems in power transformers, capacitors, and high-voltage cables by simulating streamer growth under realistic operating conditions; and
Reduce the need for costly and repetitive physical breakdown tests by providing accurate, physics-based simulation results.

### BRIEF DESCRIPTION OF THE DRAWINGS

In order to describe the technical solutions in the embodiments of the present disclosure or in the prior art more clearly, the accompanying drawings required for describing the embodiments will be briefly described below. Obviously, the accompanying drawings in the following description are merely some embodiments recorded in the present disclosure, and a person of ordinary skill in the art may still derive other drawings from these accompanying drawings.

FIG. 1 is a schematic flowchart of an insulating medium discharge streamer simulation method according to the present disclosure.

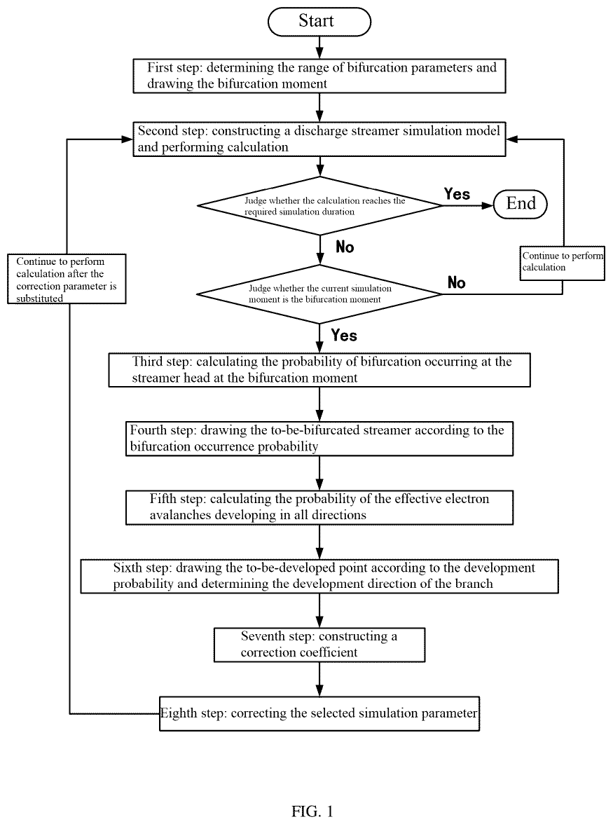

FIG. 2 is a schematic diagram of a simulation calculation process of discharge streamer offset and bifurcation according to the present disclosure.

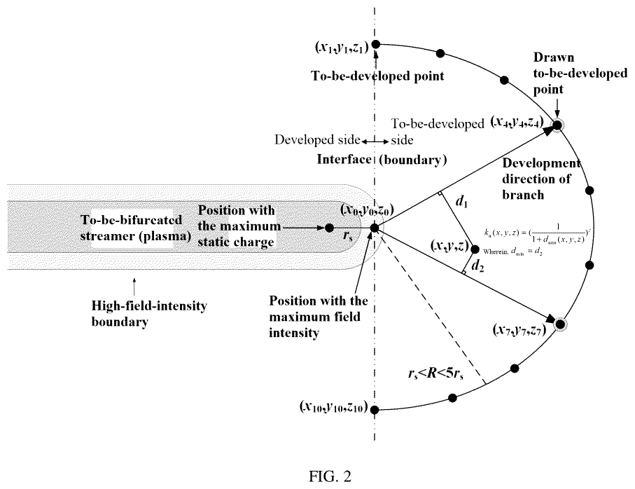

FIG. 3 shows a simulation result of space electric field distribution accompanying the streamer offset and bifurcation according to the present disclosure.

FIG. 4 shows a simulation result of space charge distribution accompanying the streamer offset and bifurcation according to the present disclosure.

FIG. 5 is a system block diagram of an insulating medium discharge streamer simulation system according to the present disclosure.

FIG. 6 is a more detailed schematic structural diagram of an insulating medium discharge streamer simulation system according to the present disclosure.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described below in conjunction with the embodiments of the present disclosure. Obviously, the described embodiments are some rather than all of the embodiments. All other embodiments obtained by a person of ordinary skill in the art based on the embodiments of the present disclosure without creative efforts shall fall within the protection scope of the present disclosure.

Therefore, the following detailed description of the embodiments of the present disclosure provided in the accompanying drawings are not intended to limit the protection scope of the present disclosure, but is merely representative of selected embodiments of the present disclosure. All other embodiments obtained by a person of ordinary skill in the art based on the embodiments of the present disclosure without creative efforts shall fall within the protection scope of the present disclosure.

It should be noted that similar reference numerals and letters represent similar items in the accompanying drawings below. Therefore, once an item is defined in one drawing, it does not need to be further defined and explained in subsequent drawings.

In the description of the present disclosure, the orientation or position relationship indicated by the terms “central”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “anticlockwise”, etc. is based on the orientation or position relationship shown in the accompanying drawings, only for the convenience of describing the present disclosure and simplifying the description, rather than indicating or implying that the device or element referred to must have a specific orientation or be constructed and operated in a specific orientation. Therefore, it should not be construed as a limitation to the present disclosure.

Besides, the terms “first” and “second” are used only for descriptive purposes and should not be construed as indicating or implying relative importance or implicitly indicating the number of indicated technical features. Thus, features defined with “first” and “second” may explicitly or implicitly include one or more of the features. In the description of the present disclosure, “plurality of” means two or more, unless otherwise specifically defined.

In the present disclosure, unless otherwise specified and defined, the terms such as “mounting” “connected”, “connection” and “fixing” should be understood in a broad sense. For example, connection may be fixed connection, detachable connection, or integrated connection; connection may be direct connection or indirect connection through an intermediate medium, and connection may be the internal communication between two elements or the interaction relationship between the two elements. A person of ordinary skill in the art may understand specific meanings of the foregoing terms in the present disclosure based on a specific situation.

In the present disclosure, unless otherwise specified and limited, the first feature “above” or “below” the second feature may include that the first feature and the second feature are in direct contact, and may also include that the first feature and the second feature are not in direct contact, but are in contact through another feature between the first feature and the second feature. Moreover, the first feature being “on” or “above” or “over” the second feature includes the first feature being directly above and obliquely above the second feature, or simply means that the level of the first feature is higher than that of the second feature. The first feature being “beneath” or “below” or “under” the second feature includes the first feature being directly below and obliquely below the second feature, or simply means that the level of the first feature is lower than that of the second feature.

In order to enable a person skilled in the art to better understand the technical solution of present disclosure, the present disclosure will be further described below in detail in conjunction with the accompanying drawings. An insulating medium streamer discharge simulation method considering offset and bifurcation includes:
an insulating medium discharge streamer simulation method considering offset and bifurcation, including the following steps:

First step: arranging an insulating medium in an electric field environment, measuring the number range [Nₚₛ, N_{pb}] of discharge streamer bifurcation points in the insulating medium and the number range of [N_{bs}, N_{bb}] of effective electron avalanches generated by each bifurcation, randomly drawing N_{bpoint}∈[Nₚₛ,N_{pb}] bifurcation points from all simulation calculation time nodes, and marking corresponding moments as bifurcation moments,
wherein in this embodiment, through observation and confirmation by a high-speed camera, Nₚₛ=0, N_{pb}=5, N_{bs}=1, N_{bb}=3, the randomly drawn N_{bpoint}=2, and the corresponding bifurcation moments are the t=0.5 nₛ moment and the t=6.4 nₛ moment respectively;

Second step: constructing a simulation model for discharge streamer in the insulating medium based on a hydrodynamic drift diffusion model and a bipolar charge carrier migration model, wherein the initial value a₀ of the average distance between molecules in the hydrodynamic drift diffusion model is set as a real constant greater than 0; performing calculation according to a specified simulation step length from the zero moment, if the calculation reaches the bifurcation moment, entering the third step and then continuing to perform calculation after the value of the average distance between molecules is updated, otherwise, continuing to perform calculation with the values of the original parameters, and ending after simulation calculation is performed for a specified simulation duration, wherein the simulation time step length is set as 0.1 ns, the simulation duration is set as 200 ns, and a₀ is set as 0.3 nm;

Third step: calculating the probability of bifurcation occurring at each streamer head at the moment when t=0.5 ns or t=6.4 ns:

$$\begin{matrix}{P}_{s - i} = \{ \begin{matrix}\frac{{\vert {E}_{s m ax - i} \vert}^{η}}{{\sum }_{i = 1}^{{n}_{s}} {\vert {E}_{s m ax - i} \vert}^{η}} & \vert {E}_{s m ax - i} \vert > {E}_{c} \\ 0 & \vert {E}_{s m ax - i} \vert \leq {E}_{c}\end{matrix} & i = 1 , 2 , … , {n}_{s} ,\end{matrix}$$

wherein i is a serial number parameter, nₛ is the total number of all streamer branches at the current moment, Pₛ₋ᵢ is the probability of bifurcation occurring at the i^{th} streamer head, Eₛₘₐₓ₋ᵢ is the maximum electric field intensity of the i^{th} streamer head, E_{c} is the threshold of the electric field for sustainable development of the streamer, the streamer with Eₛₘₐₓ₋ᵢ>E_{c} is a developable streamer, η is the streamer development probability index, and in this embodiment, E_{c} is 10⁶V/m and η is2;

Fourth step: drawing a streamer bifurcation position according to the Pₛ₋ᵢ, wherein only one bifurcation position is drawn at each bifurcation moment, the drawn streamer is referred to as a to-be-bifurcated streamer, and the bifurcation position at the position of the maximum field intensity of the head is denoted as (x₀,y₀,z₀);

Fifth step: making a 180° cambered surface or arc by taking the bifurcation position as a center of a circle and 1-5 times the radius rs of the streamer head as a radius, wherein the rs is a distance between the position of the maximum net charge density and the position of the maximum electric field intensity; dividing the cambered surface or arc into nr to-be-developed points at equal grids or equal intervals, wherein nᵣ>(5×N_{bb}) is met and nᵣ is the number of the to-be-developed points; and calculating the probability of the effective electron avalanches moving and evolving to each to-be-developed point:

$$\begin{matrix}{P}_{b - j} = \{ \begin{matrix}\frac{{\vert {ϕ}_{s m ax} - {ϕ}_{j} \vert}^{η}}{{\sum }_{j = 1}^{{n}_{s}} {\vert {ϕ}_{s m ax} - {ϕ}_{j} \vert}^{η}} & \vert {ϕ}_{s m ax} - {ϕ}_{j} \vert > {E}_{c} \\ 0 & \vert {ϕ}_{s m ax} - {ϕ}_{j} \vert \leq {ϕ}_{c}\end{matrix} & j = 1 , 2 , … , {n}_{r} ,\end{matrix}$$

wherein j is a serial number parameter, P_{b-j} is the probability of the effective avalanches moving to the j^{th} to-be-developed point, φₛₘₐₓ is the electric potential at the bifurcation position, φⱼ is the electric potential at the j^{th} to-be-developed point, η is the streamer development probability index, φ_{c} is a threshold of the effective electron avalanche development electric potential, and in this embodiment, φ_{c}=0, nᵣ=20, and the arc is made by using the radius which is 3 times rₛ;

Sixth step: randomly drawing N_{branch}=[N_{bs}, N_{bb}] effective development points from the nr to-be-developed points according to the P_{b-j}, wherein N_{branch} is the total number of the effective development points, and it is indicated that the streamer only offsets but is not bifurcated when N_{branch}=1; connecting (x₀,y₀,z₀) with the selected to-be-developed point (xₖ,yₖ, zₖ) to form a vector pointing at the to-be-developed point which is regarded as the development direction of the effective electron avalanches, wherein k=1, 2, . . . , N_{branch}, and in this embodiment, the N_{branch} randomly drawn at each of the two bifurcation moments is 2;

Seventh step: taking a plane of which the normal vector is parallel to the development direction of the to-be-bifurcated streamer and which passes through a point (x₀,y₀,z₀) as a boundary, or taking a straight line which is perpendicular to the development direction of the to-be-developed streamer and passes through a point (x₀,y₀,z₀) as a boundary, and on the to-be-developed side, calculating a distance dₖ(x,y,z) from a certain point (x,y,z) in a solving domain to a ray where the development direction of each branch is located:

$${d}_{k} ( x , y , z ) = \{ \begin{matrix}\begin{matrix}a distance to a straight line passing through \\ the point ( {x}_{0} , {y}_{0} , {z}_{0} ) and the point ( {x}_{k} , {y}_{k} , {z}_{k} )\end{matrix} & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) \geq 0 \\ a distance to the point ( {x}_{0} , {y}_{0} , {z}_{0} ) & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) < 0\end{matrix} ,$$

wherein the starting point of the ray is (x0,y0,z0), assuming that the minimum value in dₖ(x,y,z) is dₘᵢₙ(x,y,z), a correction coefficient k_{cor}(x,y,z) is constructed as follows:

$${k}_{c o r} ( x , y , z ) = {( \frac{1}{1 + {d}_{min} ( x , y , z )} )}^{γ} ,$$

wherein γ is a gradient parameter for controlling the change rate of the correction coefficient, and in this embodiment, γ is 3; and

Eighth step: correcting the average distance between molecules in the hydrodynamic drift diffusion model in the solving domain on the to-be-developed side,

$${a}_{c o r} ( x , y , z , t ) = ( 1 - m \times {K}_{c o r} ( x , y , z ) \times \frac{Δ {T}_{s} - t}{Δ {T}_{s}} ) \times {a}_{0} ,$$

wherein a_{cor} is the corrected average distance between molecules and is a function related to the spatial position and time, m is a correction scaling coefficient and meets 0<m<1, K_{cor} is the normalized result of k_{cor}, a₀ is the initial value of the average distance between molecules in the hydrodynamic drift diffusion model, ΔTₛ is a time interval between the moment of current bifurcation and the moment of next bifurcation and t is the streamer development time calculated from the beginning of current bifurcation; and updating the average distance between molecules of the discharge streamer simulation model in the second step as current corrected value and returning to the second step. In this embodiment, m is 0.8, and ΔTₛ=(6.4 nₛ-0.5 nₛ)=5.9 nₛ.

The implementation result is shown as follows:
in one embodiment, the applicant initially thought of setting the randomly distributed space charge initial condition in the solving space, which has physical significance, because the space charges in the medium are unevenly distributed under the action of external factors (such as ultraviolet rays). A Random uniform random function is set at the space charge initial condition; however, it was found that the streamer is not bifurcated, because the electric field distortion caused by the unevenly distributed initial charges gradually disappears after several time step lengths. Actually, the initial state of the space charges will rapidly change with the development of the streamer.

Although the method of the random charge distribution initial value failed, the applicant also thought of whether bifurcation will be caused if the set random space charge initial value continues to act. Therefore, the applicant set the randomly distributed background charges (not the initial value) to simulate the random factors (such as impurities and bubbles) inherent in the liquid medium. Under the action of the randomly distributed background charges, the applicant obtained the unsatisfactory simulation result. The streamer charges are intermittently distributed and not continuous, and the formed electric field channel is not obviously bifurcated. The reason is that the randomly distributed background charges do affect the electric field distortion and charge generation at the streamer head, but the development direction is not pointed for the new streamer, so the streamer is not bifurcated.

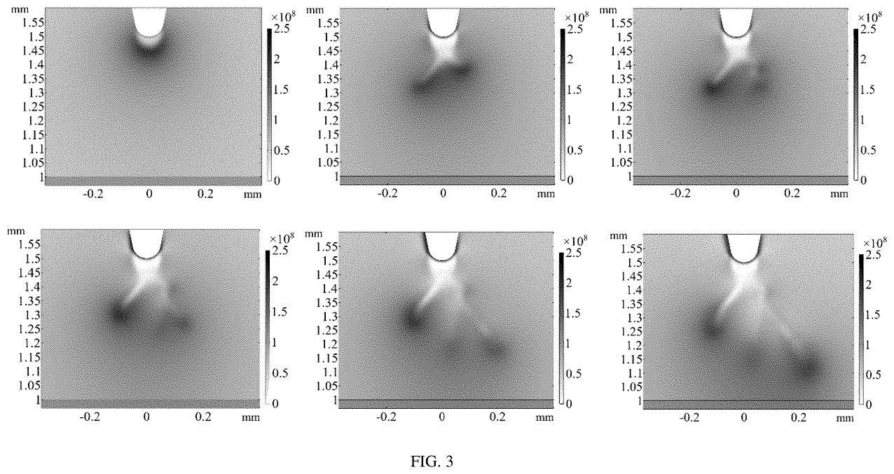

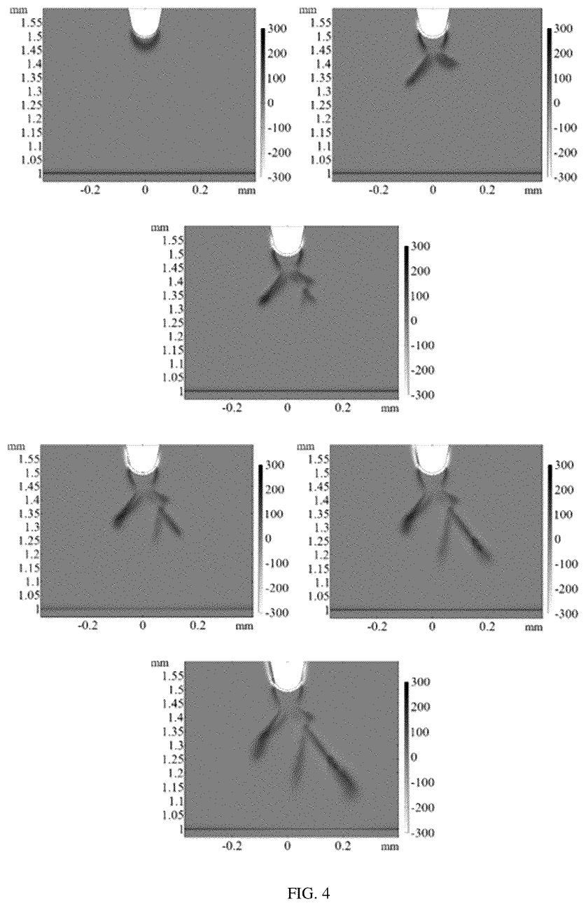

Through the above exploration, the applicant realized that in order to realize streamer bifurcation, it is necessary to start with the microscopic electron avalanche development probability, construct the development probability models in all directions and provide power for the development of new streamers. Therefore, the technical solutions of the present disclosure are put forward. The simulation result of space electric field distribution accompanying the streamer offset and bifurcation is shown in FIG. 3; and the simulation result of space charge distribution accompanying the streamer offset and bifurcation is shown in FIG. 4.

The method provided by the present disclosure has more theoretical significance because the discharge itself belongs to a probability event. Both the macroscopic random disturbance factor and the microscopic random disturbance factor are reflected in the probability change, which is more practical. However, the method for artificially setting random disturbance points (regions) can only reflect the influence of macroscopic disturbance, and it is difficult to describe a large number of discrete random disturbances by directly using mathematical formulas. Moreover, the position, number and size of the set random disturbance factors all have artificial subjective wills.

The method provided by the present disclosure has smaller calculation amount (few calculation resources and short calculation time). In the method for artificially setting random disturbance, in order to achieve considerable results, the diameter of the disturbance region needs to be controlled to 1-10 μm, and the region density is about 10¹¹ m⁻³. A large number of disturbance regions will increase the number of meshes (calculation nodes) and the calculation amount, so it is necessary to use a high-performance server for solution. The method provided by the present disclosure can be solved by using a common computer.

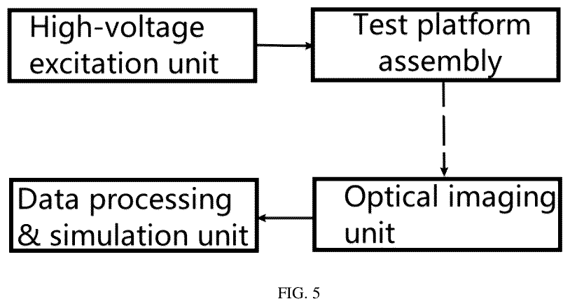

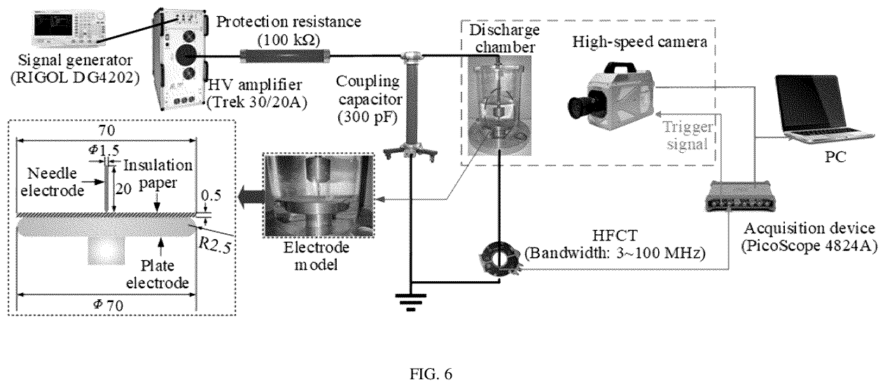

Referring to FIG. 5 and FIG. 6, an exemplary physical implementation of the insulating medium discharge streamer simulation system considering offset and bifurcation is described.

The system comprises four main physical subsystems: a test platform assembly, a high-voltage excitation unit, an optical imaging unit, and a data processing & simulation unit.
1. Test Platform Assembly:
The test platform includes a circular planar surface made of insulating material (e.g., ceramic or epoxy), with a diameter greater than that of the insulating medium sample (e.g., oil-paper composite) to ensure full support and avoid edge discharge effects.
A ground electrode is embedded beneath or attached to the platform and is electrically accessible.
The insulating medium is placed centrally on the platform.
2. High-Voltage Excitation Unit:
For example, a needle-type high-voltage electrode is mounted on a precision positioning stage, allowing it to be placed exactly 1.0 mm above the surface of the insulating medium.
A programmable high-voltage power supply (e.g., Trek 30/20 or similar) is connected between the needle electrode and the ground electrode. This supply is software-controlled to generate various electric stress waveforms including power-frequency AC (50/60 Hz), harmonics, square waves, positive/negative DC, combined AC-DC, and pulsed waveforms with adjustable rise/fall times.
3. Optical Imaging Unit:
A high-speed camera (e.g., Photron SA-Z or similar) is positioned perpendicular to the discharge region, with appropriate optical lenses and filters to capture streamer propagation events.
The camera is triggered to record discharge initiation and development.
Exemplarily, referring to FIG. 6 and according to the illustrated orientation, the system is described as follows:
RIGOL DG4202 serves as a signal generator, and Trek 30/20A acts as a high-voltage amplifier (HV amplifier). Together, they form a high-voltage power supply. Connected between this high-voltage power supply and the ground terminal are a series-connected protection resistance and a coupling capacitor. In parallel with the coupling capacitor, a discharge chamber is connected. This discharge chamber contains air and functions as the test platform.
Within the discharge chamber: the ground electrode is implemented as a plate electrode; insulation paper, serving as the insulating medium, is placed on the plate electrode; a needle electrode is positioned directly above the center of the insulation paper, with its lower tip spaced, for example, 1 mm from the insulation paper. The plate electrode is connected below to a base via a connecting rod. This base is further connected by a connecting wire to the aforementioned ground terminal and the lower terminal of the coupling capacitor. A High-Frequency Current Transformer (HFCT) is installed on this connecting wire. The upper terminal of the needle electrode is connected to the upper terminal of the coupling capacitor.
Based on the current sensed by the HFCT, acquisition device generates a trigger signal for a high-speed camera. This trigger signal enables the high-speed camera to capture images of the discharge and allows a personal computer (PC) to acquire the images captured by the high-speed camera.
4. Data Processing & Simulation Unit: The personal computer (PC) receives image sequences from the high-speed camera via a high-speed interface (e.g., Camera Link or GigE Vision).
An operator reviews the images to manually measure (or via image analysis software) the observed range of bifurcation points [N_ps, N_pb] and effective electron avalanches per bifurcation [N_bs, N_bb]. These measured ranges are input into the simulation software as empirical constraints.
The PC runs commercial finite-element simulation software (COMSOL Multiphysics® or ANSYS®) in which the method disclosed in the present invention is implemented via custom scripts or user-defined modules.
The simulation proceeds according to the aforementioned steps.
The output includes 2D or 3D visualizations of space electric field distribution (as shown in FIG. 3) and space charge distribution (as shown in FIG. 4).

### Practical Application & Industrial Utility:

The system is not merely a mathematical simulation tool but an integrated hardware-software apparatus used in high-voltage insulation laboratories.

It serves to:
Validate and calibrate simulation models against real physical discharge events;
Guide the development of new insulating materials by predicting their discharge behavior under complex electric stresses;
Improve the design of insulation systems in power transformers, capacitors, and high-voltage cables by simulating streamer growth under realistic operating conditions; and
Reduce the need for costly and repetitive physical breakdown tests by providing accurate, physics-based simulation results.

In one embodiment, an insulating medium discharge streamer simulation system considering offset and bifurcation, comprising:
a test platform comprising a substantially planar surface for supporting the insulating medium, and a ground electrode electrically connected to said platform;
a high-voltage electrode disposed opposite and spaced apart from said planar surface to form an electric field environment with the ground electrode;
a programmable high-voltage power supply electrically connected to the high-voltage electrode and the ground electrode, configured to apply at least one of AC, DC, composite AC-DC, or pulsed electric stress to the insulating medium;
a high-speed camera positioned to capture real-time discharge images of streamer development within the insulating medium; and
a computer system operatively connected to the high-speed camera, said computer system comprising a processor and a memory storing executable instructions, wherein the processor is configured to:
receive the discharge images from the high-speed camera;
measure, based on analysis of said discharge images, the number range [Nₚₛ, N_{pb}] of discharge streamer bifurcation points in the insulating medium and the number range of [N_{bs}, N_{bb}] of effective electron avalanches generated by each bifurcation, draw N_{bpoint}∈[Nₚₛ, N_{pb}] bifurcation points from all simulation calculation time nodes randomly and mark corresponding moments as bifurcation moments, wherein Nₚₛ and N_{pb} are the minimum value and the maximum value of the number of the discharge streamer bifurcation points respectively, N_{bs} and N_{bb} are the minimum value and the maximum value of the effective electron avalanches respectively, and N_{bpoint} is the number of the randomly drawn bifurcation points;
construct a simulation model for discharge streamer in the insulating medium based on a hydrodynamic drift diffusion model and a bipolar charge carrier migration model, wherein the initial value a₀ of the average distance between molecules in the hydrodynamic drift diffusion model is set as a real constant greater than 0; perform calculation according to a specified simulation step length from the zero moment, wherein if the calculation reaches the bifurcation moment, the processor updates the average distance between molecules and continues calculation, otherwise continues calculation with the values of the original parameters, and end after simulation calculation is performed for a specified simulation duration;
calculate the probability of bifurcation occurring at each streamer head at a certain bifurcation moment:

$${P}_{s - i} = \{ \begin{matrix}\frac{{\vert {E}_{s m ax - i} \vert}^{η}}{{\sum }_{i = 1}^{{n}_{s}} {\vert {E}_{s m ax - i} \vert}^{η}} & \vert {E}_{s m ax - i} \vert > {E}_{c} \\ 0 & \vert {E}_{s m ax - i} \vert \leq {E}_{c}\end{matrix} \qquad i = 1 , 2 , … , {n}_{s} ,$$

wherein i is a serial number parameter, nₛ is the total number of all streamer branches at the current moment, Pₛ₋ᵢ is the probability of bifurcation occurring at the i^{th} streamer head, Eₛₘₐₓ₋ᵢ is the maximum electric field intensity of the i^{th} streamer head, E_{c} is the threshold of the electric field for sustainable development of the streamer, the streamer with Eₛₘₐₓ₋ᵢ>E_{c} is a developable streamer, and η is the streamer development probability index;
draw a streamer bifurcation position according to the Pₛ₋ᵢ, wherein only one bifurcation position is drawn at each bifurcation moment, the drawn streamer is referred to as a to-be-bifurcated streamer, the bifurcation position at the position of the maximum field intensity of the head is denoted as (x₀,y₀,z₀), x₀ is the X-axis coordinates of the bifurcation position, y₀ is the Y-axis coordinates of the bifurcation position, and z₀ is the Z-axis coordinates of the bifurcation position;
make a 180° cambered surface or arc by taking the bifurcation position as a center of a circle and 1-5 times the radius rₛ of the head of the streamer as a radius, wherein the rₛ is a distance between the position of the maximum net charge density and the position of the maximum electric field intensity; divide the cambered surface or arc into nr to-be-developed points at equal grids or equal intervals, wherein nᵣ>(5×N_{bb}) is met and nᵣ is the number of the to-be-developed points; and calculate the probability of the effective electron avalanches moving and evolving to each to-be-developed point:

$${P}_{b - j} = \{ \begin{matrix}\frac{{\vert {ϕ}_{s m ax} - {ϕ}_{j} \vert}^{η}}{{\sum }_{j = 1}^{{n}_{s}} {\vert {ϕ}_{s m ax} - {ϕ}_{j} \vert}^{η}} & \vert {ϕ}_{s m ax} - {ϕ}_{j} \vert > {E}_{c} \\ 0 & \vert {ϕ}_{s m ax} - {ϕ}_{j} \vert \leq {ϕ}_{c}\end{matrix} \qquad j = 1 , 2 , … , {n}_{r} ,$$

wherein j is a serial number parameter, P_{b-j} is the probability of the effective avalanches moving to the j^{th} to-be-developed point, φₛₘₐₓ is the electric potential at the bifurcation position, φⱼ is the electric potential at the j^{th} to-be-developed point, η is the streamer development probability index, and φ_{c} is a threshold of the effective electron avalanche development electric potential;
draw N_{branch}=[N_{bs}, N_{bb}] effective development points from the nᵣ to-be-developed points randomly according to the P_{b-j}, wherein N_{branch} is the total number of the effective development points, and it is indicated that the streamer only offsets but is not bifurcated when N_{branch}=1; connect (x₀,y₀,z₀) with the selected to-be-developed point (xₖ,yₖ,zₖ) to form a vector pointing at the to-be-developed point which is regarded as the development direction of the effective electron avalanches, wherein xₖ is the X-axis coordinates of the k^{th} effective development point, yₖ is the Y-axis coordinates of the k^{th} effective development point, zₖ is the Z-axis coordinates of the k^{th} effective development point, and k=1, 2, . . . , N_{branch};

take a plane of which the normal vector is parallel to the development direction of the to-be-bifurcated streamer and which passes through a point (x₀,y₀,z₀) as a boundary, or take a straight line which is perpendicular to the development direction of the to-be-developed streamer and passes through a point (x₀,y₀,z₀) as a boundary, and on the to-be-developed side, calculate a distance dₖ(x,y,z) from a certain point (x,y,z) in a solving domain to a ray where the development direction of each branch is located:

$${d}_{k} ( x , y , z ) = \{ \begin{matrix}\begin{matrix}a distance to a straight line passing through \\ the point ( {x}_{0} , {y}_{0} , {z}_{0} ) and the point ( {x}_{k} , {y}_{k} , {z}_{k} )\end{matrix} & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) \geq 0 \\ a distance to the point ( {x}_{0} , {y}_{0} , {z}_{0} ) & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) < 0\end{matrix} ,$$

wherein the starting point of the ray is (x₀,y₀,z₀), assuming that the minimum value in dₖ(x,y,z) is dₘᵢₙ(x,y,z), a correction coefficient k_{cor}(x,y,z) is constructed as follows:

$${k}_{c o r} ( x , y , z ) = {( \frac{1}{1 + {d}_{min} ( x , y , z )} )}^{γ} ;$$

wherein γ is a gradient parameter for controlling the change rate of the correction coefficient; and
correct the average distance between molecules in the hydrodynamic drift diffusion model in the solving domain on the to-be-developed side,

$${a}_{c o r} ( x , y , z , t ) = ( 1 - m \times {K}_{c o r} ( x , y , z ) \times \frac{Δ {T}_{s} - t}{Δ {T}_{s}} ) \times {a}_{0} ,$$

wherein a_{cor} is the corrected average distance between molecules and is a function related to the spatial position and time, m is a correction scaling coefficient and meets 0<m<1, K_{cor} is the normalized result of k_{cor}, ΔTₛ is a time interval between the moment of current bifurcation and the moment of next bifurcation and t is the streamer development time calculated from the beginning of current bifurcation; and update the average distance between molecules in the simulation model to current corrected value; and continue the calculation from the point of update, thereby iteratively performing the simulation until the specified simulation duration is reached.

In another embodiment, the system also comprises an output unit coupled to the computer system, configured to display simulation results including space electric field distribution and space charge distribution accompanying the streamer offset and bifurcation. Exemplarily, the output unit is a display screen or display system coupled to the computer system.

In another embodiment, wherein the processor is further configured such that when simulating a positively polar streamer, the positively polar streamer development probability index is 2-3, and when simulating a negatively polar streamer, the negatively polar streamer development probability index is 1.5-2.

In another embodiment, wherein the gradient parameter γ is greater than 1.

In another embodiment, wherein the electric field threshold E_{c} of the effective electron avalanche development is greater than or equal to 0, and the electric potential difference threshold φ_{c} of the effective electron avalanche development is greater than or equal to 0.

Finally, it should be noted that the described embodiments are merely some rather than all of the embodiments. Based on the embodiments of the present application, all the other embodiments obtained by those skilled in the art without inventive effort are within the protection scope of the present application.

Some exemplary embodiments of the present disclosure are described above only by illustration. Undoubtedly, those of ordinary skill in the art may modify the described embodiments in various ways without departing from the spirit and scope of the present disclosure. Therefore, the above drawings and descriptions are essentially illustrative and should not be construed as limiting the protection scope of the claims of the present disclosure.

What is claimed is:

1. An insulating medium discharge streamer simulation system considering offset and bifurcation, comprising:
a test platform comprising a substantially planar surface for supporting the insulating medium, and a ground electrode electrically connected to said platform;
a high-voltage electrode disposed opposite and spaced apart from said planar surface to form an electric field environment with the ground electrode;
a programmable high-voltage power supply electrically connected to the high-voltage electrode and the ground electrode, configured to apply at least one of AC, DC, composite AC-DC, or pulsed electric stress to the insulating medium;
a high-speed camera positioned to capture real-time discharge images of streamer development within the insulating medium; and
a computer system operatively connected to the high-speed camera, said computer system comprising a processor and a memory storing executable instructions, wherein the processor is configured to:
receive the discharge images from the high-speed camera;
measure, based on analysis of said discharge images, the number range [Nₚₛ, N_{pb}] of discharge streamer bifurcation points in the insulating medium and the number range of [N_{bs}, N_{bb}] of effective electron avalanches generated by each bifurcation, draw N_{bpoint}∈[Nₚₛ,N_{pb}] bifurcation points from all simulation calculation time nodes randomly and mark corresponding moments as bifurcation moments, wherein Nₚₛ and N_{pb} are the minimum value and the maximum value of the number of the discharge streamer bifurcation points respectively, N_{bs} and N_{bb} are the minimum value and the maximum value of the effective electron avalanches respectively, and N_{bpoint} is the number of the randomly drawn bifurcation points;
construct a simulation model for discharge streamer in the insulating medium based on a hydrodynamic drift diffusion model and a bipolar charge carrier migration model, wherein the initial value a₀ of the average distance between molecules in the hydrodynamic drift diffusion model is set as a real constant greater than 0; perform calculation according to a specified simulation step length from the zero moment, wherein if the calculation reaches the bifurcation moment, the processor updates the average distance between molecules and continues calculation, otherwise continues calculation with the values of the original parameters, and end after simulation calculation is performed for a specified simulation duration;
calculate the probability of bifurcation occurring at each streamer head at a certain bifurcation moment:
$${P}_{s - i} = \{ \begin{matrix}\frac{{\vert {E}_{s m ax - i} \vert}^{η}}{{\sum }_{i = 1}^{{n}_{s}} {\vert {E}_{s m ax - i} \vert}^{η}} & \vert {E}_{s m ax - i} \vert > {E}_{c} \\ 0 & \vert {E}_{s m ax - i} \vert \leq {E}_{c}\end{matrix} \qquad i = 1 , 2 , … , {n}_{s} ,$$
wherein i is a serial number parameter, nₛ is the total number of all streamer branches at the current moment, Pₛ₋ᵢ is the probability of bifurcation occurring at the i^{th} streamer head, Eₛₘₐₓ₋ᵢ is the maximum electric field intensity of the i^{th} streamer head, E_{c} is the threshold of the electric field for sustainable development of the streamer, the streamer with Eₛₘₐₓ₋ᵢ>E_{c} is a developable streamer, and η is the streamer development probability index;
draw a streamer bifurcation position according to the Pₛ₋ᵢ, wherein only one bifurcation position is drawn at each bifurcation moment, the drawn streamer is referred to as a to-be-bifurcated streamer, the bifurcation position at the position of the maximum field intensity of the head is denoted as (x₀,y₀,z₀), x₀ is the X-axis coordinates of the bifurcation position, y₀ is the Y-axis coordinates of the bifurcation position, and z₀ is the Z-axis coordinates of the bifurcation position;
make a 180° cambered surface or arc by taking the bifurcation position as a center of a circle and 1-5 times the radius rₛ of the head of the streamer as a radius, wherein the rₛ is a distance between the position of the maximum net charge density and the position of the maximum electric field intensity; divide the cambered surface or arc into nᵣ to-be-developed points at equal grids or equal intervals, wherein nᵣ>(5×N_{bb}) is met and nᵣ is the number of the to-be-developed points; and calculate the probability of the effective electron avalanches moving and evolving to each to-be-developed point:
$${P}_{b - j} = \{ \begin{matrix}\frac{{\vert {ϕ}_{s m ax} - {ϕ}_{j} \vert}^{η}}{{\sum }_{j = 1}^{{n}_{s}} {\vert {ϕ}_{s m ax} - {ϕ}_{j} \vert}^{η}} & \vert {ϕ}_{s m ax} - {ϕ}_{j} \vert > {E}_{c} \\ 0 & \vert {ϕ}_{s m ax} - {ϕ}_{j} \vert \leq {ϕ}_{c}\end{matrix} \qquad j = 1 , 2 , … , {n}_{r} ,$$
wherein j is a serial number parameter, P_{b-j} is the probability of the effective avalanches moving to the j^{th} to-be-developed point, φₛₘₐₓ is the electric potential at the bifurcation position, φⱼ is the electric potential at the j^{th} to-be-developed point, η is the streamer development probability index, and φ_{c} is a threshold of the effective electron avalanche development electric potential;
draw N_{branch}∈[N_{bs}, N_{bb}] effective development points from the nᵣ to-be-developed points randomly according to the P_{b-j}, wherein N_{branch} is the total number of the effective development points, and it is indicated that the streamer only offsets but is not bifurcated when N_{branch}=1; connect (x₀,y₀,z₀) with the selected to-be-developed point (xₖ,yₖ,zₖ) to form a vector pointing at the to-be-developed point which is regarded as the development direction of the effective electron avalanches, wherein xₖ is the X-axis coordinates of the k^{th} effective development point, yₖ is the Y-axis coordinates of the k^{th} effective development point, zₖ is the Z-axis coordinates of the k^{th} effective development point, and k=1, 2, . . . , N_{branch};
take a plane of which the normal vector is parallel to the development direction of the to-be-bifurcated streamer and which passes through a point (x₀,y₀,z₀) as a boundary, or take a straight line which is perpendicular to the development direction of the to-be-developed streamer and passes through a point (x₀,y₀,z₀) as a boundary, and on the to-be-developed side, calculate a distance dₖ(x,y,z) from a certain point (x,y,z) in a solving domain to a ray where the development direction of each branch is located:
$${d}_{k} ( x , y , z ) = \{ \begin{matrix}\begin{matrix}a distance to a straight line passing through \\ the point ( {x}_{0} , {y}_{0} , {z}_{0} ) and the point ( {x}_{k} , {y}_{k} , {z}_{k} )\end{matrix} & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) \geq 0 \\ a distance to the point ( {x}_{0} , {y}_{0} , {z}_{0} ) & ( {x}_{0} - {x}_{k} ) ( {x}_{0} - x ) + ( {y}_{0} - {y}_{k} ) ( {y}_{0} - y ) + ( {z}_{0} - {z}_{k} ) ( {z}_{0} - z ) < 0\end{matrix} ,$$
wherein the starting point of the ray is (x₀,y₀,z₀), assuming that the minimum value in dₖ(x,y,z) is dₘᵢₙ(x,y,z), a correction coefficient k_{cor}(x,y,z) is constructed as follows:
$${k}_{c o r} ( x , y , z ) = {( \frac{1}{1 + {d}_{min} ( x , y , z )} )}^{γ} ;$$
wherein γ is a gradient parameter for controlling the change rate of the correction coefficient; and
correct the average distance between molecules in the hydrodynamic drift diffusion model in the solving domain on the to-be-developed side,
$${a}_{c o r} ( x , y , z , t ) = ( 1 - m \times {K}_{c o r} ( x , y , z ) \times \frac{Δ {T}_{s} - t}{Δ {T}_{s}} ) \times {a}_{0} ,$$
wherein a_{cor} is the corrected average distance between molecules and is a function related to the spatial position and time, m is a correction scaling coefficient and meets 0<m<1, K_{cor} is the normalized result of k_{cor}, ΔTₛ is a time interval between the moment of current bifurcation and the moment of next bifurcation and t is the streamer development time calculated from the beginning of current bifurcation; and update the average distance between molecules in the simulation model to current corrected value; and continue the calculation from the point of update, thereby iteratively performing the simulation until the specified simulation duration is reached.

2. The insulating medium discharge streamer simulation system considering offset and bifurcation according to claim 1, the system also comprises an output unit coupled to the computer system, configured to display simulation results including space electric field distribution and space charge distribution accompanying the streamer offset and bifurcation.

3. The insulating medium discharge streamer simulation system considering offset and bifurcation according to claim 1, wherein the processor is further configured such that when simulating a positively polar streamer, the positively polar streamer development probability index is 2-3, and when simulating a negatively polar streamer, the negatively polar streamer development probability index is 1.5-2.

4. The insulating medium discharge streamer simulation system considering offset and bifurcation according to claim 1, wherein the gradient parameter γ is greater than 1.

5. The insulating medium discharge streamer simulation system considering offset and bifurcation according to claim 1, wherein the electric field threshold E_{c} of the effective electron avalanche development is greater than or equal to 0, and the electric potential difference threshold φ_{c} of the effective electron avalanche development is greater than or equal to 0.
